(19) United States
(12) Patent Application Publication
(10) Pub. No.: US 2025/0243330 A1
(43) Pub. Date: Jul. 31, 2025

(54) METHOD OF PREPARING TRANSPARENT RESIN LAYER AND METHOD OF MANUFACTURING DISPLAY APPARATUS INCLUDING TRANSPARENT RESIN LAYER

(71) Applicant: Samsung Display Co., LTD., Yongin-si (KR)

(72) Inventors: Kyunghee Lee, Yongin-si (KR); Taemin Kim, Yongin-si (KR); Donggeun Shin, Yongin-si (KR); Seunghee Lee, Yongin-si (KR)

(21) Appl. No.: 19/034,470

(22) Filed: Jan. 22, 2025

(30) Foreign Application Priority Data
Jan. 26, 2024 (KR) 10-2024-0012445

(51) Int. Cl. C08J 3/28; H10H 29/01

(52) U.S. Cl. CPC C08J 3/28; H10H 29/0362; C08J 2300/12

(57) ABSTRACT

Provided is a method of preparing a transparent resin layer, the method including forming a photocurable composition layer by applying a photocurable composition onto a substrate including a first region; performing (a) an exposure process of covering the first region of the photocurable composition layer with a mask and exposing the first region with a first light; and performing (b) an exposure process of exposing an entire surface of the photocurable composition layer with a second light, wherein the first light cures the photocurable composition layer more firmly than the second light does.

### CROSS-REFERENCE TO RELATED APPLICATION

The present application claims priority to and the benefit of Korean Patent Application No. 10-2024-0012445, filed on Jan. 26, 2024, in the Korean Intellectual Property Office, the entire content of which is hereby incorporated by reference.

### BACKGROUND

### 1. Field

One or more embodiments of the present disclosure relate to a method of preparing a transparent resin layer and a method of manufacturing a display apparatus including a transparent resin layer prepared by the method of preparing a transparent resin layer.

### 2. Description of the Related Art

A display apparatus in the art includes an emission unit on a substrate on which a thin-film transistor (TFT) is provided, a display panel including a light control unit that controls light emission from the emission unit, and a window unit on the display panel. Glass has been used for each of the substrate of the display panel and the window unit. However, recently, in consideration of flexible characteristics of some display panels and/or the like, display apparatuses in which polyimide is used for the substrate of the display panel and a transparent resin layer is used instead of glass for the window unit have been developed. Here, the transparent resin layer forms an overcoat layer on the light control unit.

### SUMMARY

To replace glass with a transparent resin layer, a set or certain hardness level should be utilized, but hardness of a transparent resin layer should vary depending on a region of a display panel in consideration of the possibility of deterioration, bending, and/or the like of a light-emitting device upon an opening part. In this regard, one or more embodiments include a method of preparing a transparent resin layer that is capable of adjusting hardness according to a region while using a same material, and a method of manufacturing a display apparatus including the transparent resin layer.

Additional aspects of embodiments will be set forth in part in the description which follows and, in part, will be apparent from the description, or may be learned by practice of the presented embodiments of the present disclosure.

According to one or more embodiments, a method of preparing a transparent resin layer includes:
forming a photocurable composition layer by applying a photocurable composition onto a substrate including a first region,
performing (a) an exposure process of covering the first region of the photocurable composition layer with a mask and exposing the first region with a first light, and
performing (b) an exposure process of exposing an entire surface of the photocurable composition layer with a second light.

The first light may cure the photocurable composition layer more firmly (or more completely) than the second light does.

In an embodiment, the first light may be light of a shorter wavelength region than that of the second light, or the first light may further include light of a shorter wavelength region than that of the second light.

In an embodiment, the intensity of the first light may be greater than that of the second light.

The (a) exposure process may be followed by the (b) exposure process, or the (b) exposure process may be followed by the (a) exposure process.

In an embodiment, the second light may be obtained by installing, on a light source of an exposure apparatus, a bandpass filter that blocks or reduces transmission of a short-wavelength region.

In an embodiment, the first light may have wavelengths in an ultraviolet region and a visible light region, and the second light may have wavelengths in a visible light region.

In an embodiment, the first light may have an emission peak in a region of about 300 nm to about 600 nm, and the second light may have an emission peak in a region of about 500 nm to about 600 nm.

A hardness of a transparent resin layer in the region covered with the mask may be lower than a hardness of a transparent resin layer in a region not covered with the mask.

An average surface hardness of the transparent resin layer may be adjusted by adjusting an area ratio of the region covered with the mask and the region not covered with the mask.

According to one or more embodiments, a method of manufacturing a display apparatus includes:
providing a display panel including a first region,
forming a light control unit on the display panel, and
forming an overcoat layer on the light control unit,
wherein the forming of the overcoat layer includes:
forming a photocurable composition layer by applying a photocurable composition onto a light control unit,
performing (a) an exposure process of covering the first region of the photocurable composition layer with a mask and exposing the first region with a first light, and
performing (b) an exposure process of exposing an entire surface of the photocurable composition layer with a second light,

The first light may cure the photocurable composition layer more firmly (or more completely) than the second light does.

In an embodiment, the first light may be light of a shorter wavelength region than that of the second light, or the first light may further include light of a shorter wavelength region than that of the second light.

In an embodiment, the intensity of the first light may be greater than that of the second light.

The (a) exposure process may be followed by the (b) exposure process, or the (b) exposure process may be followed by the (a) exposure process.

In an embodiment, the first light may be obtained without installing a bandpass filter on a light source of an exposure apparatus, and the second light may be obtained by installing a bandpass filter on a light source of an exposure apparatus. The bandpass filter may block or reduce transmission of a portion of the short-wavelength region of the light source.

In an embodiment, the first light may have an emission peak in a region of about 300 nm to about 600 nm, and the second light may have an emission peak in a region of about 500 nm to about 600 nm.

The entire hardness of the overcoat layer may be adjusted by adjusting an area ratio of the region covered with the mask and the region not covered with the mask.

In an embodiment, the display panel may include a luminescent region and a non-luminescent region, and the first region may be the luminescent region.

In an embodiment, the display panel may be a flexible panel, and the first region may be a bending region.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a flowchart illustrating a transparent resin layer formation method according to an embodiment;

FIG. 2 is a flowchart illustrating a transparent resin layer formation method according to another embodiment;

FIGS. 3A-3D are diagrams sequentially illustrating a display apparatus manufacturing method according to an embodiment;

FIGS. 4A-4D are diagrams sequentially illustrating a display apparatus manufacturing method according to an embodiment;

FIG. 5 shows an emission spectrum of a light source that has passed through the bandpass filter of Test Examples 1 to 4;

FIG. 6 shows an emission spectrum of a light source on which bandpass filters of Test Examples 1 to 4 are not installed;

FIGS. 7-10 are each a photograph of the surface of overcoat layers of samples of Test Examples 1 to 4 after performing a scuff test thereon; and

FIGS. 11-12 show graphs of measuring light transmittance according to wavelength of samples formed in the same manner as Test Examples 1 and 14, respectively.

### DETAILED DESCRIPTION

Reference will now be made in more detail to embodiments of the present disclosure, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As embodiments allows for various suitable changes and numerous embodiments, example embodiments will be illustrated in the drawings and described in more detail in the written description. An effect and a characteristic of the disclosure, and a method of accomplishing these will be apparent when referring to embodiments described with reference to the drawings. The subject matter of the disclosure may, however, be embodied in many different forms and should not be construed as limited to the embodiments set forth herein.

Hereinafter, embodiments of the disclosure will be described in more detail with reference to the accompanying drawings. The same or corresponding components will be denoted by the same reference numerals, and thus redundant description thereof will be omitted.

It will be understood that although the terms “first,” “second,” etc. may be used herein to describe various components, these components should not be limited by these terms. These components are only used to distinguish one component from another.

An expression used in the singular encompasses the expression of the plural, unless it has a clearly different meaning in the context.

It will be further understood that the terms “comprises” and/or “comprising” used herein specify the presence of stated features or elements, but do not preclude the presence or addition of one or more other features or elements.

It will be understood that when a layer, region, or component is referred to as being “on” or “onto” another layer, region, or component, it may be directly or indirectly formed on the other layer, region, or component. For example, intervening layers, regions, or components may be present.

Sizes of elements in the drawings may be exaggerated for convenience of explanation. In other words, because sizes and thicknesses of components in the drawings may be arbitrarily illustrated for convenience of explanation, the following embodiments are not limited thereto.

When an example is implemented differently, a specific process order may be performed differently from the described order. For example, two processes described in succession may be performed substantially at the same time, or may be performed in an order opposite to the order in which they are described.

In the examples below, it will be understood that when a film, region, or component is referred to as being “connected to” another film, region, or component, the film, region, or component may be not only directly connected to the another film, region, or component, but also indirectly connected to the another film, region, or component as intervening film, region, or component is present. For example, in the present specification, it will be understood that when a film, region, or component is referred to as being “electrically connected to” another film, region, or component, the film, region, or component may be not only directly electrically connected to the another film, region, or component, or but also indirectly electrically connected to the another film, region, or component as intervening film, region, or component is present.

### Transparent Resin Layer Formation Method

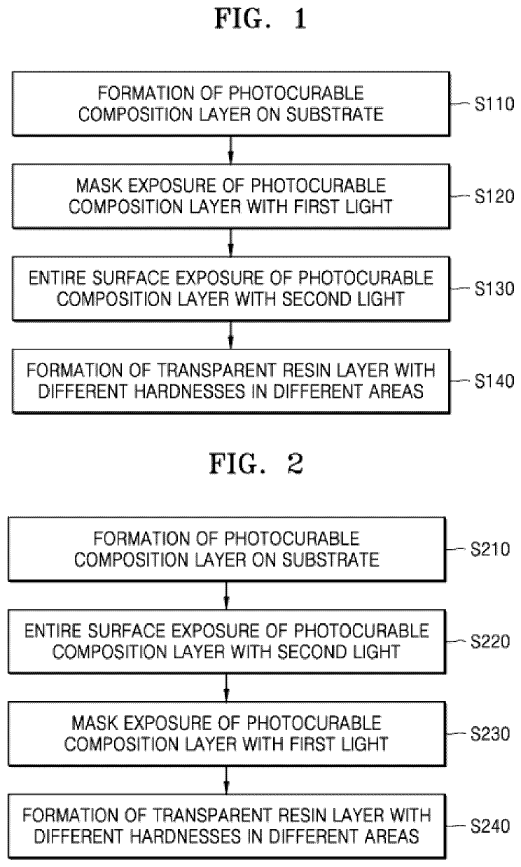

FIG. 1 is a flowchart illustrating a transparent resin layer formation method according to an embodiment. Referring to FIG. 1, a photocurable composition for forming a transparent resin layer may be applied onto a substrate (S110). The substrate is a substrate on which a transparent resin layer is to be formed, and may be, for example, a display panel including a light-emitting device thereon. The display panel may be formed on a glass substrate and/or a plastic substrate such as, for example, polyimide.

The photocurable composition is a composition that is cured by light exposure to form a transparent resin layer. The photocurable composition may include a monomer including a functional group of photopolymerization, a photoinitiator, and a solvent, and may further include an additive, such as, for example, a leveling agent and a sensitizer, inorganic particles for modulus control, and/or the like. For use as the photocurable composition, any suitable photocurable composition suitable for forming a transparent resin layer generally used in the art may be used. The photocurable composition may be, for example, a composition that forms a polysilsequioxane resin.

The photocurable composition may be applied onto the substrate by using a suitable or appropriate method, such as, for example, spin coating, inkjet printing, slit coating, and/or the like, to form a photocurable composition layer. The photocurable composition may form a photocurable composition layer containing no solvent or a solvent in a reduced amount, due to evaporation of the solvent during the applying of the photocurable composition onto the substrate.

The photocurable composition layer may be exposed with a first light by using a mask (S120). In embodiments, a transparent resin layer to be formed has a different hardness depending on a region. For example, in embodiments, a transparent resin layer has a low hardness in some regions to allow for bending, and a high hardness in some regions not to allow for bending. As such, regions having low hardness may be covered first, and the photocurable composition layer may be exposed with the first light. In embodiments, the exposure may be performed by using an exposure apparatus and a mask. The first light may be a light having conditions capable of facilitating curing of the photocurable composition layer. For example, the first light may have conditions under which a photoinitiator used in the photocurable composition operates efficiently. The photocurable composition layer in regions exposed with the first light, e.g., in regions not covered with the mask, may be cured firmly (or more completely). In embodiments, the photocurable composition layer in regions covered with the mask may not undergo curing.

Subsequently, the entire surface of the photocurable composition layer may be exposed with the second light (S130). By removing the mask, even the photocurable composition layer in regions not cured in S120 may be cured with the second light.

The second light may be able to cure the photocurable composition layer less firmly (or less completely) than the first light does. For example, the second light may have conditions under which a photoinitiator used in the photocurable composition operates less efficiently. In an embodiment, the second light may mainly include light components in a low energy and long-wavelength region by installing a bandpass filter that blocks or reduces transmission of a shorter wavelength region and passes a longer wavelength region on a light source of an exposure apparatus. In one or more embodiments, the first light may include all shorter wavelength regions of the light source without being installed with a bandpass filter.

For example, a high-pressure mercury UV lamp may be used as the light source of the exposure apparatus. The high-pressure mercury UV lamp may emit light in a region of about 200 nm to about 800 nm. When the bandpass filter is not installed on the light source of the exposure apparatus, all the short-wavelength light, e.g., light in a region of about 380 nm or less, emitted from the high-pressure mercury UV lamp may be used to cure the photocurable composition. Because light having a wide energy range including short-wavelength regions is used, the curing rate of the photocurable composition layer may be increased. When the bandpass filter is not installed on the light source of the exposure apparatus, light in a limited range in the low energy region may be used, resulting in a lower curing rate of the photocurable composition layer than the case not using the bandpass filter. In an embodiment, the exposure energy may be, for example, in a range of tens of mJ to 1 J, but may vary depending on process conditions and/or the like.

For example, the first light may include wavelengths in an ultraviolet region and a visible light region, and the second light may include only wavelengths in a visible light region. For example, the first light may include wavelengths in an ultraviolet region and a visible light region, and the second light may include wavelengths in only a long-wavelength region among a visible light region. For example, the first light may have an emission peak in a region of about 200 nm to about 800 nm, and the second light may have an emission peak in a region of about 400 nm to about 700 nm. For example, the first light may have an emission peak in a region of about 300 nm to about 600 nm, and the second light may have an emission peak in a region of about 500 nm to about 600 nm.

In an embodiment, the intensity of the first light may be greater than that of the second light. In an embodiment, the first light and the second light may be in the same wavelength range, and the intensity of the first light may be greater than that of the second light. In one or more embodiments, the first light and the second light may have different wavelength ranges as descried above, and the intensity of the first light may be greater than that of the second light. The greater the intensity of light, the more firmly (or more completely) the photocurable composition layer may be cured.

In embodiments, the region exposed with the first light may be exposed repeatedly by the entire surface exposure with the second light, resulting in the curing more firmly (or more completely) than the case of the exposure with the first light only.

As such, a transparent resin layer having different hardnesses in different regions may be formed by sequentially exposing the photocurable composition with a high-energy first light using a mask and then a low-energy second light without using a mask (S140).

In an embodiment, by adjusting the size of a mask, the area ratio of the masked region of the photocurable composition layer to the unmasked region of the photocurable composition layer may be adjusted, and in this regard, the average surface hardness of the transparent resin layer formed by curing may be adjusted. For example, when the surface hardness of the transparent resin layer in the masked region is 3H, the surface hardness of the transparent resin layer in the unmasked region may be 8H, and the area ratio of the masked region to the unmasked region during curing may be 3:7, the average surface hardness of the transparent resin layer may be roughly estimated as 3H×0.3+8H×0.7-6.5H. In embodiments, when the masked region and the unmasked region are evenly (or substantially evenly) mixed and distributed, the average surface hardness of the transparent resin layer may be meaningfully adjusted.

FIG. 2 is a flowchart illustrating a transparent resin layer formation method according to another embodiment. Referring to FIG. 2, the formation of a photocurable composition layer on a substrate (S210) may be the same as S110 described above. The transparent resin layer formation method of this embodiment differs from the previous embodiment only in that the order of the curing with the mask and the curing without the mask are reversed. For example, in this embodiment, the entire surface exposure with the second light may be performed without using a mask (S220), followed by the exposure using a mask with the first light (S230), thereby forming a transparent resin layer (S240). For descriptions of the first light, the second light, and the mask, reference may be made to the first light, the second light, and the mask described in connection with FIG. 1.

### Display Apparatus Manufacturing Method

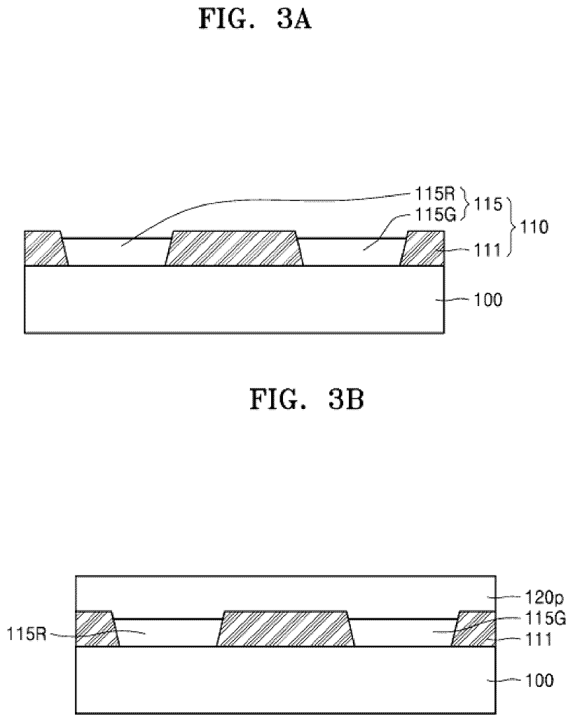

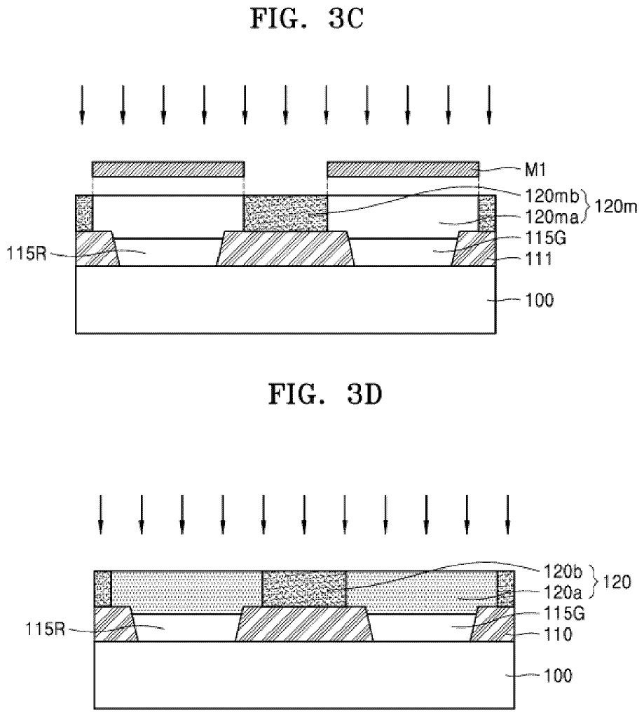

FIGS. 3A-3D are diagrams sequentially illustrating a display apparatus manufacturing method according to an embodiment. Referring to FIG. 3A, a display panel 100 on which a color filter layer 110 is provided may be provided. The display panel 100 may include or consist of a substrate and a driving device and a light-emitting device that are on the substrate. The color filter layer 110 may include color filter patterns 115R, 115G, and 115B (not shown) and partition walls 111 separating the color filter patterns. In this embodiment, only the color filter layer 110 is shown, but a display apparatus may further include a quantum dot color conversion layer under the color filter layer 110. The color filter layer 110 and the quantum dot color conversion layer may constitute a light converter.

In one or more embodiments, the display panel 100 without the color filter layer 110 thereon may be provided. In embodiments, a transparent resin layer may be directly on the display panel 100.

Referring to FIG. 3B, a photocurable composition for forming a transparent resin layer may be applied onto the color filter layer 110 to form a photocurable composition layer 120p. The photocurable composition is a composition that may be cured by light exposure to form a transparent resin layer. The transparent resin layer thus may be an overcoat layer. The overcoat layer may flatten the gradients made by the color filter layer 110 and protect a display apparatus.

The photocurable composition may include a monomer including a functional group for photopolymerization, a photoinitiator, and a solvent, and may further include an additive, such as a leveling agent and a sensitizer, inorganic particles for modulus control, and/or the like. For use as the photocurable composition, any suitable photocurable composition suitable for forming a transparent resin layer generally used in the art may be used. The photocurable composition may be, for example, a composition that forms a polysilsequioxane resin. The photocurable composition may be applied onto the substrate by using a suitable or appropriate method such as spin coating, inkjet printing, and/or slit coating to form a photocurable composition layer. The photocurable composition may form the photocurable composition layer 120p containing no solvent or a solvent in a reduced amount due to evaporation of the solvent during the process of applying the photocurable composition onto the substrate.

Referring to FIG. 3C, a portion of the photocurable composition layer 120p may be covered with a mask M1 and exposed with the first light. The region covered with the mask M1 may include a region where the light-emitting device at the bottom is exposed through the color filter pattern 115, a so-called opening region. In one or more embodiments where a display apparatus does not include the color filter layer 110, a region where the light-emitting device at the bottom is directly provided, a so-called opening region, may be included. The region not covered with the mask M1 may include a region where the light-emitting device is not exposed, a so-called non-opening region.

The first light may be light capable of facilitating curing of the photocurable composition layer. For example, the first light may have a wavelength according to conditions under which a photoinitiator included in the photocurable composition acts efficiently, for example, a wide range of wavelengths in a short-wavelength region of an ultraviolet region and/or in an ultraviolet region and a visible light region. Also, the first light may have an intensity suitable for efficient curing. Accordingly, a region 120 mb of the photocurable composition layer not covered with the mask M1 may be cured firmly (or more completely) with the first light. In embodiments, a region 120 ma of the photocurable composition layer covered with the mask M1 may not (or substantially may not) undergo curing. When the light-emitting device is exposed to short-wavelength light such as an ultraviolet ray, materials may deteriorate and the device may be damaged. Because the light-emitting device located in an opening is not exposed to the first light due to the mask M1, the light-emitting device is not (or substantially not) damaged when cured by the first light.

As the light source of the exposure apparatus for photocuring, for example, a mercury lamp and/or an LED lamp may be used, but is not limited thereto. Any suitable light source having a suitable or appropriate wavelength range and a suitable or appropriate intensity may be used. In an embodiment, the first light may use the entire wavelength range of the light source without installing a filter on the light source. The curing efficiency may be increased by using a wide range of wavelengths, including short wavelengths, as the first light for curing. In one or more embodiments, a bandpass filter that passes a short-wavelength region and/or an ultraviolet region may be installed on the light source of the exposure apparatus so that only the wavelength range that is efficient for curing may be used.

Referring to FIG. 3D, the entire surface of a photocurable composition layer 120m may be exposed with the second light. Because the mask M1 has been removed, even the region 120ma that has not been cured in the first exposure process may be cured by the second light.

The second light may be light in a longer wavelength region than the first light, and for example, light in a low energy region. For example, the first light may include wavelengths in an ultraviolet region, and the second light may include a visible light region without including wavelengths in an ultraviolet region.

In an embodiment, the second light may use the same light source as the first light. By installing a bandpass filter that blocks or reduces transmission of a shorter wavelength region and passes a longer wavelength region on the same light source of the exposure apparatus, the second light may mainly include light components in a long-wavelength region. For example, the first light may have an emission peak in a region of about 200 nm to about 800 nm, and the second light may have an emission peak in a region of about 400 nm to about 700 nm by cutting light below 400 nm from the first light. For example, the first light may have an emission peak in a region of about 300 nm to about 600 nm, and the second light may have an emission peak in a region of about 500 nm to about 600 nm by cutting, blocking, or reducing transmission of light below 500 nm from the first light by using the bandpass filter.

When the photocurable composition layer 120m is cured by the second light, an overcoat layer 120 may be formed. A region 120a of the overcoat layer 120 cured only by the second light may have a lower hardness than a region 120b of the overcoat layer 120 cured by both the first light and the second light. For example, the region 120a of the overcoat layer 120 may have a surface hardness of 3H to 4H, whereas the region 120b, e.g., a non-opening region, of the overcoat layer 120 may have a surface hardness of 7H to 8H. In embodiments, by adjusting the size of the mask, the average surface hardness of the overcoat layer 120 may be adjusted. In embodiments, the mask may be prepared to cover all the openings, but the size of the mask may be different. For example, when the surface hardness of the overcoat layer in the masked region by the first light is 3H, the surface hardness of the overcoat layer in the unmasked region by the first light may be 8H, and the mask may be prepared such that the proportion of the area being masked is 40%, the average surface hardness of the overcoat layer may be roughly estimated to be 3H×0.4+8H×0.6=6H. When the mask is prepared such that the proportion of the area being masked is 30%, the average surface hardness of the overcoat layer may be roughly estimated to be 3H×0.3+8H×0.7=6.5H.

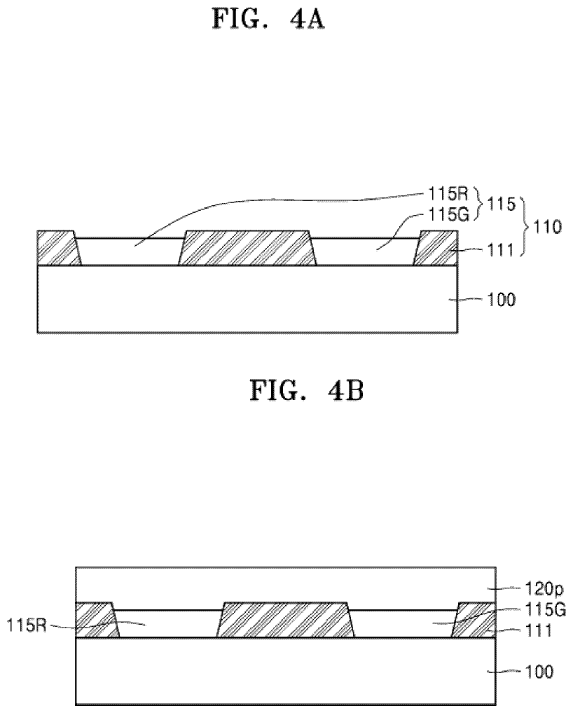

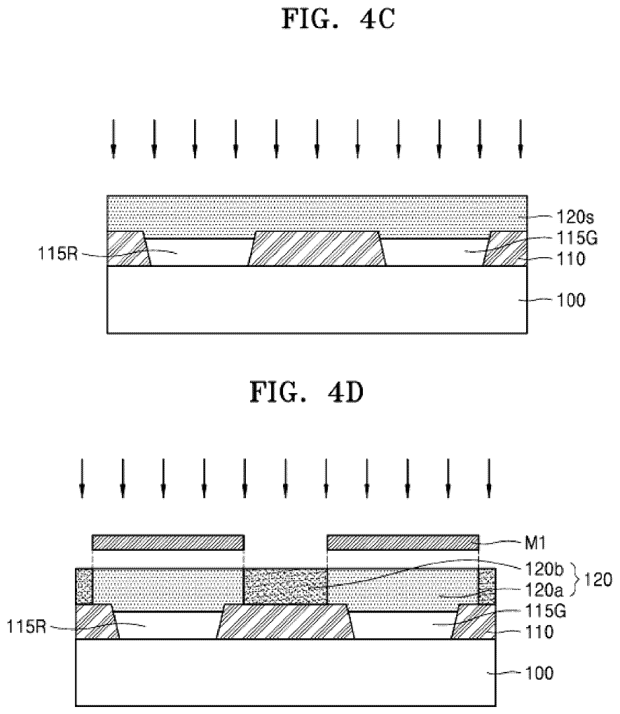

FIGS. 4A-4D are diagrams sequentially illustrating the display apparatus manufacturing method according to other embodiments. The display apparatus manufacturing method of this embodiment differs from embodiments of FIGS. 3A-3D in that the order of the curing with the mask and the curing without the mask are reversed. For descriptions of FIGS. 4A and 4B, reference may be made to the descriptions of FIGS. 3A-3B, and the first light, the second light, the mask M1, and other common reference numerals may be understood by referring to the descriptions of FIGS. 3A-3D.

Referring to FIG. 4C, the entire surface of a photocurable composition layer 120p may be exposed with the second light. The second light may be understood in connection with the second light described in the embodiments of FIGS. 3A-3D. By the entire surface exposure with the second light, an entirely cured photocurable composition layer 120s may be formed (e.g., while the photocurable composition layer is not completely or entirely cured, the entire photocurable composition layer is at least partially cured). The photocurable composition layer 120s may be cured to the same hardness as the region 120a of the photocurable composition layer described in the embodiments of FIGS. 3A-3D.

Referring to FIG. 4D, a portion of the photocurable composition layer 120s may be covered with a mask M1 and exposed with the first light. The first light may be understood in connection with the first light described in the embodiments of FIGS. 3A-3D. The embodiment of FIGS. 4A-4D is the same as the embodiments of FIGS. 3A-3D in that the non-opening region 120b exposed by the mask M1 may undergo curing by both the first light and the second light, and the opening region 120a covered by the mask M1 may undergo curing only by the second light. However, the embodiment of FIG. 4D is different from the embodiments of FIGS. 3A-3D in that the non-opening region 120b in the embodiment of FIG. 4D may be cured by the second light first and cured by the first light, as opposed to the embodiments of FIGS. 3A-3D in which the non-opening region 120b may be cured by the first light and then cured by the second light. In this embodiment, the overall hardness of the overcoating layer may also be adjusted by adjusting the mask size.

For a flexible display apparatus, the hardness of the overcoat layer should be lower in a bending region than in other regions. When the hardness of the overcoat layer in the bending region is too high, the overcoat layer may break during a bending operation. Although the display apparatus manufacturing method is described in the embodiments above to form the overcoat layer having low hardness in the opening region, a display apparatus may be manufactured to form an overcoat layer having lower hardness in the bending region by applying the same method.

### EXAMPLES

### Test Example 1

On a panel having a color filter pattern thereon, a photocurable composition including a polysilsesquioxane resin that forms an overcoat layer was applied by inkjet printing to form a photocurable composition layer.

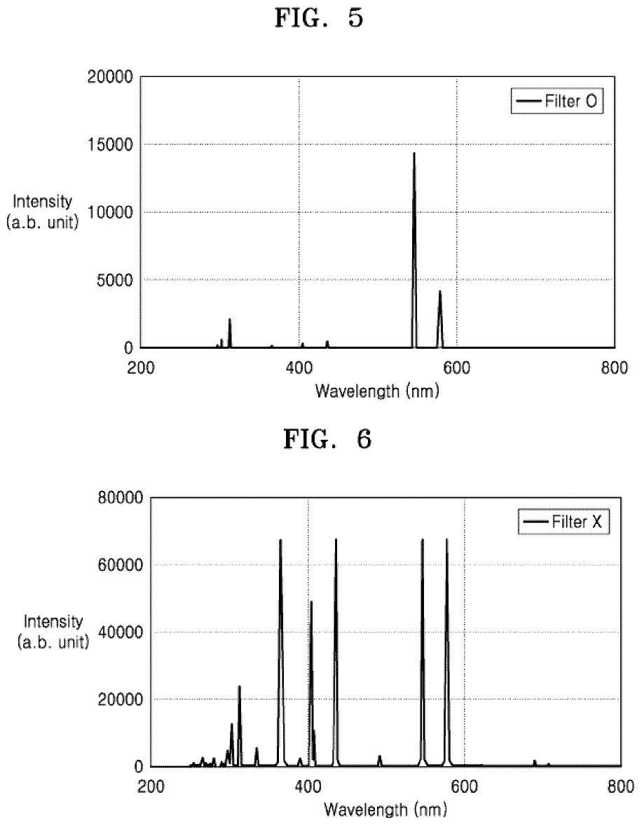

The panel on which the photocurable composition layer was formed was placed in an exposure apparatus, and irradiated with an exposure light source installed with a bandpass filter at 0.5 J to expose the photocurable composition layer. As the light source of the exposure apparatus, a high-pressure mercury UV lamp was used. The emission spectrum of the light source that passed through the bandpass filter is shown in FIG. 5. Referring to FIG. 5, the light source had a main emission peak between 500 nm and 600 nm. The photocurable composition layer was cured by the exposure to form an overcoat layer having a thickness of about 10 μm. The thickness of the overcoat layer may vary in different regions due to gradients made by the color filter pattern.

### Test Example 2

On a panel having a color filter pattern thereon, a photocurable composition including a polysilsesquioxane resin that forms an overcoat layer was applied by inkjet printing to form a photocurable composition layer. In the same manner as Test Example 1, the panel on which the photocurable composition layer was formed was placed in an exposure apparatus. Then, by irradiating the panel with a light source installed with a bandpass filter at 0.5 J, the photocurable composition layer underwent a first exposure process.

Subsequently, the color filter pattern was covered with an exposure mask, and then irradiated with an exposure light source not installed with a bandpass filter at 0.5 J to perform a second exposure process on the photocurable composition layer resulting from the first exposure process. The emission spectrum of the light source not installed with the bandpass filter is shown in FIG. 6. Referring to FIG. 6, the light source further included an emission peak between 300 nm and 500 nm in addition to an emission peak between 500 nm and 600 nm.

The photocurable composition layer was cured by the first and second exposure processes to form an overcoat layer having a thickness of about 10 μm. Here, the area covered by the exposure mask was about 25% of the total area of the overcoat layer.

### Test Example 3

An overcoat layer was formed in the same manner as in Test Example 2, except that an exposure mask was changed so that the area covered by the exposure mask was about 40%.

### Test Example 4

An overcoat layer was formed in the same manner as in Test Example 1, except that the bandpass filter was not installed on the exposure apparatus.

### Hardness Measurement Results

For each of the overcoat layers formed in Test Examples 1 to 4, the surface hardness was measured by using a pencil hardness measuring device (CT-PC2 manufactured by Coretech company) and a scuff tester, and the measurement results thereof are shown in Table 1.

Referring to Table 1, the overcoat layer of Test Example 1 had the lowest pencil hardness of 3H, the overcoat layer of Test Example 4 had the highest pencil hardness of 8H, the overcoat layer of Test Example 2 had a pencil hardness of 7H, and the overcoat layer of Test Example 3 had a pencil hardness of 5.5H.

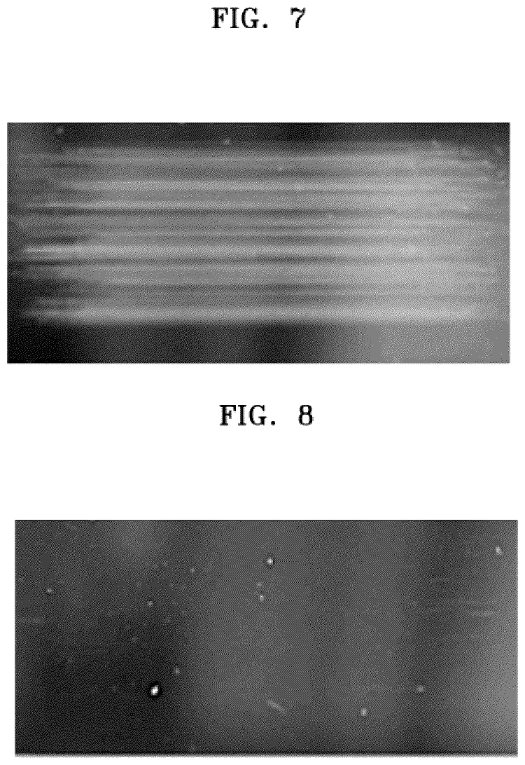

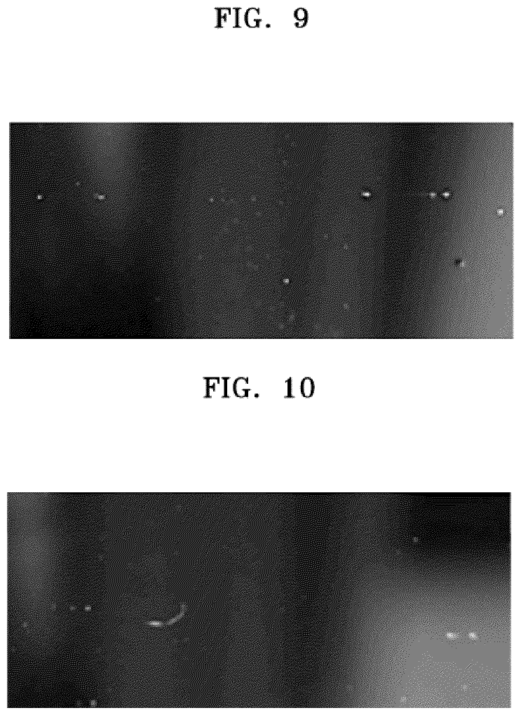

FIGS. 7-10 are each a photograph of the surface of the overcoat layers of samples of Test Examples 1 to 4 after performing a scuff test thereon. The scuff test was performed by placing a weight on top of the overcoat layer and pressing down with a force of about 1.5 kgf to move steel wool #0000 10 times from side to side and back and forth. Referring to FIGS. 7-10 and Table 1, severe linear scratches were made in the overcoat layer of Test Example 1 in the moving direction of the steel wool, and dot scratches were made in the overcoat layers of Test Examples 2 to 4. Here, the overcoat layer of Test Example 4 had the fewest scratches, and the overcoat layers of Test Examples 2 and 3 had more scratches than the overcoat layer of Test Example 4 but much fewer scratches than the overcoat layer of Test Example 1.

TABLE 1

| | | Scuff test |
|---|---|---|
| | Pencil hardness | (1.5 kgf/10 time) |
| Test Example 1 | 3H | Many linear scratches |
| Test Example 2 | 7H | Dot scratches |
| Test Example 3 | 5.5H | Dot scratches |
| Test Example 4 | 8H | Dot scratches |

Referring to the hardness measurements and scuff test results of samples of Test Examples 1 to 4, it can be seen that the hardness of the overcoat layer may be adjusted by two-step exposure.

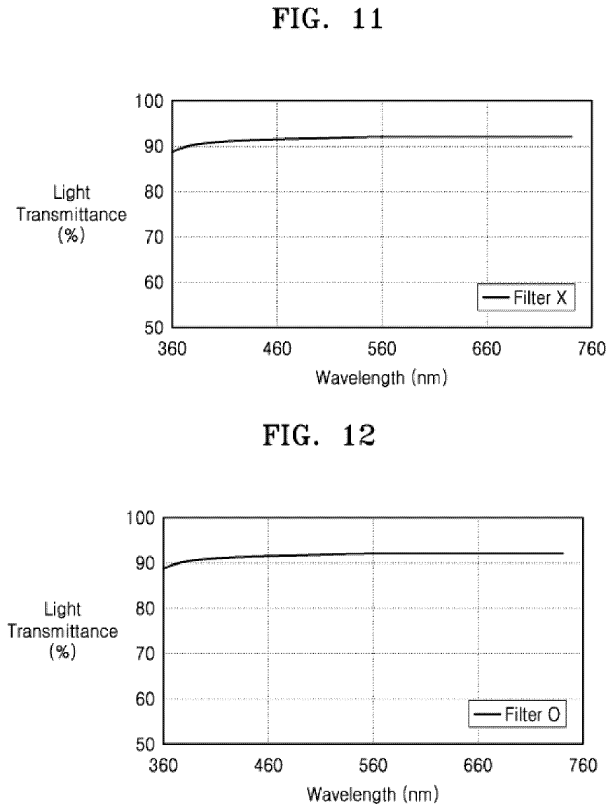

FIG. 11 shows a graph of measurements of light transmittance according to wavelength of samples where the overcoat layer was formed in the same manner as in Test Example 1 on a glass substrate instead of the panel having the color filter pattern formed thereon. FIG. 12 shows a graph of measurements of light transmittance according to wavelength of samples where the overcoat layer was formed in the same manner as in Test Example 4 on a glass substrate instead of the panel having the color filter pattern formed thereon. Referring to FIGS. 11-12, the light transmittance curves in both graphs are the same (or substantially the same). Accordingly, it can be seen that light transmittance of an overcoat layer was not affected by whether or not a bandpass filter was used.

According to the one or more embodiments, by adjusting an exposure wavelength and performing two-step exposure using a mask in one step, the hardness of a transparent resin layer may be adjusted depending on a location while using the same material.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that various suitable changes in form and details may be made therein without departing from the spirit and scope as defined by the following claims, and equivalents thereof.

What is claimed is:

1. A method of preparing a transparent resin layer, the method comprising:
forming a photocurable composition layer by applying a photocurable composition onto a substrate including a first region;
performing (a) an exposure process of covering the first region of the photocurable composition layer with a mask and exposing the first region with a first light; and
performing (b) an exposure process of exposing an entire surface of the photocurable composition layer with a second light,
wherein the first light cures the photocurable composition layer more firmly than the second light does.

2. The method of claim 1, wherein the first light comprises light in a shorter wavelength region than that of the second light, or the first light further comprises light in a shorter wavelength region than that of the second light.

3. The method of claim 1, wherein the first light has a greater intensity than the second light.

4. The method of claim 1, wherein the (a) exposure process is followed by the (b) exposure process.

5. The method of claim 1, wherein the (b) exposure process is followed by the (a) exposure process.

6. The method of claim 1, wherein the second light is obtained by installing, on a light source of an exposure apparatus, a bandpass filter that reduces transmission of a short-wavelength region.

7. The method of claim 1, wherein the first light has wavelengths in an ultraviolet region and a visible light region, and the second light has wavelengths a visible light region.

8. The method of claim 1, wherein the first light has an emission peak in a region of about 300 nm to about 600 nm, and the second light has an emission peak in a region of about 500 nm to about 600 nm.

9. The solid electrolyte of claim 1, wherein a hardness of a transparent resin layer in the region covered with the mask is lower than a hardness of a transparent resin layer in a region not covered with the mask.

10. The method of claim 1, wherein an average surface hardness of the transparent resin layer is adjusted by adjusting an area ratio of the region covered with the mask and a region not covered with the mask.

11. A method of manufacturing a display apparatus, the method comprising:
providing a display panel comprising a first region;
forming a light control unit on the display panel; and
forming an overcoat layer on the light control unit,
wherein the forming of the overcoat layer comprises:
forming a photocurable composition layer by applying a photocurable composition onto a light control unit;
performing (a) an exposure process of covering the first region of the photocurable composition layer with a mask and exposing the first region with a first light; and
performing (b) an exposure process of exposing an entire surface of the photocurable composition layer with a second light,
wherein the first light cures the photocurable composition layer more firmly than the second light does.

12. The method of claim 11, wherein the first light comprises light in a shorter wavelength region than that of the second light, or the first light further comprises light in a shorter wavelength region than that of the second light.

13. The method of claim 11, wherein the first light has a greater intensity than the second light.

14. The method of claim 11, wherein:
the (a) exposure process is followed by the (b) exposure process, or
the (b) exposure process is followed by the (a) exposure process.

15. The method of claim 11, wherein:
the first light is obtained without installing a bandpass filter on a light source of an exposure apparatus, and
the second light is obtained by installing a bandpass filter on a light source of an exposure apparatus.

16. The method of claim 15, wherein the bandpass filter reduces transmission of a portion of a short-wavelength region of the light source.

17. The method of claim 11, wherein the first light has an emission peak in a region of about 300 nm to about 600 nm, and the second light has an emission peak in a region of about 500 nm to about 600 nm.

18. The method of claim 11, wherein an entire hardness of the overcoat layer is adjusted by adjusting an area ratio of the region covered with the mask and a region not covered with the mask.

19. The method of claim 11, wherein the display panel comprises a luminescent region and a non-luminescent region, and
the first region is the luminescent region.

20. The method of claim 11, wherein:
the display panel is a flexible panel, and
the first region is a bending region.
